(19) United States
(12) Patent Application Publication
(10) Pub. No.: US 2011/0074448 A1
(43) Pub. Date: Mar. 31, 2011

(54) POTENTIOMETER

(76) Inventors: Petr Zeman, Palkovice (CZ); Marian Fiedor, Mosty U Jablunkova (CZ); Veronika Fiedor, Ceske Budejovice (CZ)

(21) Appl. No.: 12/740,772

(22) PCT Filed: Sep. 25, 2008
(86) PCT No.: PCT/EP2008/062825

§ 371 Date: Apr. 30, 2010

(30) Foreign Application Priority Data
Oct. 30, 2007 (DE) 10 2007 051 869.4

(51) Int. Cl. G01R 27/08

(52) U.S. Cl. 324/691

(57) ABSTRACT

Fill level sensors designed as potentiometers are known, having two resistor strips on an electrically insulating carrier, on each of which a plurality of conductor segments are disposed at a distance from each other and act together with a pickup shoe that can move relative to the carrier, wherein the conductor segments of the one resistor strip are disposed offset from the resistors of the other resistor strip in the direction of motion of the pickup shoe. The pickup shoe electrically connects one conductor segment of the one resistor strip to a conductor segment of the other resistor strip. In order to contact the two conductor segments to be bridged, the pickup shoe has two contacts. When, however, one contact of the pickup shoe contacts a conductor segment of the one resistor strip, the other contact is in the intermediate space between the conductor segments of the other resistor strip, due to the offset arrangement of the conductor segments, so that, under some circumstances, no electrical connection is made between the conductor segments to be bridged, and no output signal is present. The conductor segments of the two resistor strips and the contacts of the pickup shoe are made of expensive metal alloys comprising noble metal. For the potentiometer according to the invention, the production costs are reduced. According to the invention, the conductor segments (5.3) of the one resistor strip (3) extend into the intermediate spaces (10) between the conductor segments (5.4) of the other resistor strip (4).

### PRIOR ART

The invention is based on a potentiometer as generically defined by the preamble to the main claim. From German Patent Disclosure DE 44 39 829 Al, a fill level transducer embodied as a potentiometer is already known, having two resistor tracks located on an electrically insulating substrate, on each of which resistor track a plurality of spaced-apart conductor segments are provided, which cooperate with a wiper that is movable relative to the substrate, and the conductor segments of one resistor track are offset from the conductor segments of the other resistor track in the direction of motion of the wiper. The wiper connects a respective conductor segment of one resistor track electrically to a conductor segment of the other resistor track. For contacting the two conductor segments to be bridged, the wiper has two contacts. However, if one contact of the wiper contacts a conductor segment of one resistor track, then the other contact, because of the offset arrangement of conductor segments, is located in the interstice between the conductor segments of the other resistor track, so that under some circumstances, an electrical connection between the conductor segments to be bridged is not made, and there is no output signal. The conductor segments of the two resistor tracks and the contacts of the wiper are made from expensive metal alloys, which contain noble metal, such as gold and/or silver.

### ADVANTAGES OF THE INVENTION

The potentiometer of the invention having the definitive characteristics of the body of the main claim has the advantage over the prior art that for producing the conductor segments of the two resistor tracks, a smaller total amount of metal alloy is required, and the production costs are thus markedly lowered, because the conductor segments of one resistor track extend into the interstices between the conductor segments of the other resistor track. Because the conductor segments mesh with one another according to the invention, fewer conductor segments per resistor track are required for approximately the same resolution of the output signal, and thus the material expense for metal alloy drops.

By the provisions recited in the dependent claims, advantageous refinements of and improvements to the potentiometer recited in the main claim are possible.

It is especially advantageous if the conductor segments of the two resistor tracks are disposed at a predetermined angle transverse to the direction of motion of the wiper. In an advantageous version, the predetermined angle is in the range between 70 and 80° . In this angular range, a secure electrical contact between the conductor segments of the two resistor tracks is attained.

It is moreover advantageous that there is a respective predetermined spacing between the conductor segment, extending into the interstice, of one resistor track and the two adjacent conductor segments of the other resistor track. The wiper connects a respective conductor segment of one resistor track electrically to an adjacent conductor segment of the other resistor track and bridges them in this way.

It is highly advantageous if the wiper has at least four spring contacts, connected to one another, which electrically contact the respective conductor segments of the resistor tracks. In this way, the conductor segments to be bridged are contacted with certainty, so that an output signal is assured. Each of the two adjacent conductor segments to be bridged are as a rule contacted by two spring contacts each.

In an advantageous feature, the wiper has five spring contacts, connected to one another, which electrically contact the conductor segments of the resistor tracks. If one of the five spring contacts breaks off over the course of time, then each of the two adjacent conductor segments to be bridged can still be contacted by two spring contacts each.

### DRAWINGS

Exemplary embodiments of the invention are shown in simplified form in the drawings and described in further detail in the ensuing description.

FIG. 1 shows a slide potentiometer according to the invention, shown in simplified form;

FIG. 2 is a side view of the potentiometer of the invention of FIG. 1;

FIG. 3 is a printed circuit board of a rotary potentiometer according to the invention.

### DESCRIPTION OF THE EXEMPLARY EMBODIMENTS

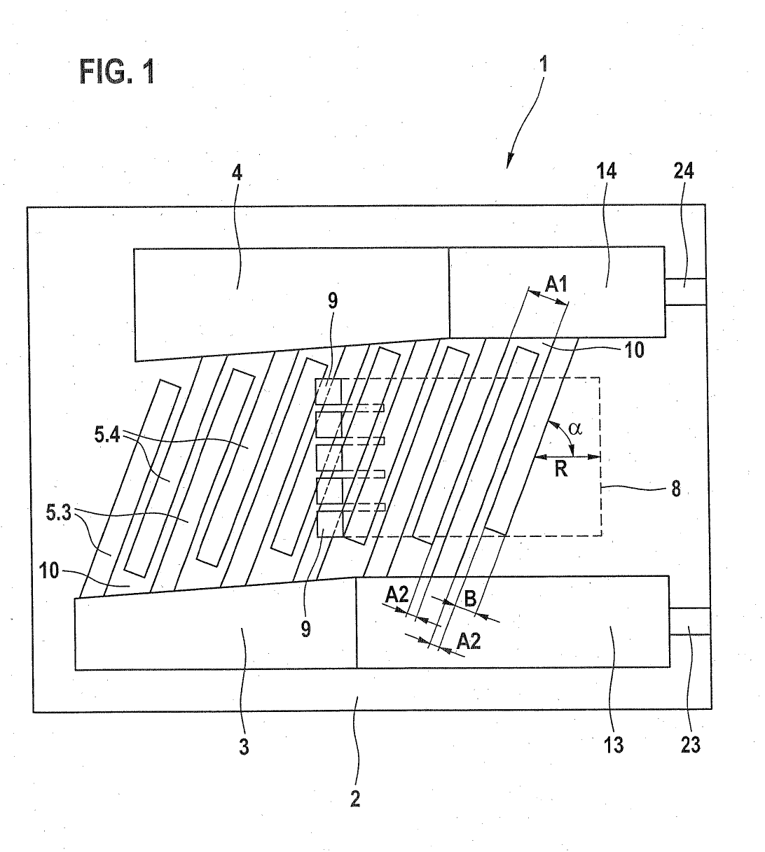

FIG. 1 shows a potentiometer according to the invention, shown in simplified form.

The potentiometer splits an input voltage into two component voltages. It serves for example as a position sensor and can be used as a slide potentiometer for determining a linear position or as a rotary potentiometer for determining an angular position.

The potentiometer 1 has an electrically insulating substrate 2, on which two electrically conductive resistor tracks 3, 4 are applied. The electrically insulating substrate 2 is embodied as a substrate plate or substrate printed circuit board, which is produced for instance from a ceramic The resistor tracks 3, 4 are film resistors, which are made from known resistor pastes and are applied two-dimensionally, for instance by means of thin- or thick-film techniques or in some other way.

On each of the sides, facing toward one another, of the resistor tracks 3, 4, a plurality of electrically conductive conductor segments 5.3, 5.4 are provided. The conductor segments 5.3, 5.4 are applied to the substrate 2, for instance again by means of thin- or thick-film techniques or in some other way, and are each electrically connected to the associated resistor track 3, 4. The conductor segments 5.3, 5.4 are produced for instance from a metal alloy, and in comparison to the resistor tracks 3, 4, they have a slight electrical resistance. They extend from their resistor track 3, 4 in the direction of the opposite resistor track 3, 4. The conductor segments 5.3, 5.4 are embodied for instance in riblike, striplike, rectangular, triangular, or fingerlike shape. In this way, each resistor track 3, 4, together with its conductor segments 5.3, 5.4, has a comblike shape. The metal alloy of the conductor segments 5.3, 5.4, to improve the fuel resistance, contains noble metals, such as gold, silver, palladium, and/or platinum.

The resistor tracks 3, 4 and their conductor segments 5.3, 5.4 are disposed in linear fashion (FIG. 1) for a slide potentiometer and in curved fashion (FIG. 3) for a rotary potentiometer. Both in the slide potentiometer and the rotary potentiometer, the two resistor tracks 3, 4 extend in the same direction. The potentiometer of the invention, particularly in the rotary potentiometer version, can be used as a fill level transducer for fuel tanks or other containers.

The potentiometer 1 has a wiper 8, shown in dashed lines and movable relative to the substrate 2, with at least two contacts 9 that contact the corresponding conductor segments 5.3, 5.4. The wiper 8 is linearly displaceable in the version as a linear potentiometer and is supported rotatably about a pivot point in the version as a rotary potentiometer. In both cases, the wiper is moved transversely to the conductor segments 5.3, 5.4.

The individual conductor segments 5.3, 5.4 of one resistor track 3, 4 have a predetermined width B and a predetermined spacing Al to one another. The individual conductor segments 5.3, 5.4 of one resistor track 3, 4 are for instance disposed parallel to one another. Between two adjacent conductor segments 5.3, 5.4 of one resistor track 3, 4, an interstice 10 is therefore formed.

The conductor segments 5.3 of one resistor track 3 are disposed offset from the conductor segments 5.4 of the other resistor track 4 in the direction of motion R of the wiper 8.

According to the invention, it is provided that the conductor segments 5.3 of one resistor track 3 extend into the interstices 10 between the conductor segments 5.4 of the other resistor track 4, and vice versa. By the meshing according to the invention of the conductor segments 5.3, 5.4, fewer conductor segments 5.3, 5.4 per resistor track 3, 4 are required, for approximately the same resolution of the output signal, so that the expense for metal alloy material for each resistor track 3, 4 drops, and thus the production costs can be reduced markedly. Compared to the prior art, only approximately half as many conductor segments 5.3, 5.4 per resistor track 3, 4 are needed. In the prior art, a total of approximately twice as many conductor segments is required as in the invention. The conductor segments 5.3, 5.4 extend to at least half their length into the interstices 10. For instance, they extend to near the opposite resistor track 3, 4.

Moreover, each of the conductor segments 5.3, 5.4 of both resistor tracks 3, 4 are disposed at a predetermined angle a to the direction of motion R of the wiper 8. For instance, the conductor segments 5.3, 5.4 are inclined, such that the at least four contacts 9, disposed side by side, of the wiper 8 contacts only the two conductor segments 5.3, 5.4 to be bridged, and not any of the others. According to the invention, the predetermined angle a is in the range between 70 and 80°. Preferably, it is approximately 73°.

Between the conductor segment 5.3, extending into the interstice 10, of one resistor track 3 and the two adjacent conductor segments 5.4 of the other resistor track 4, there is a respective predetermined spacing A2. The spacing A2 may for instance amount to approximately half the width B of one conductor segment 5.3, 5.4.

The wiper 8, via the contacts 9, connects at least one conductor segment 5.3 of one resistor track 3 electrically to at least one adjacent conductor segment 5.4 of the other resistor track 4 and in this way bridges the conductor segments 5.3, 5.4. If two adjacent conductor segments 5.3, 5.4, belonging to the same resistor track 3, 4, are connected to one another via the wiper 8, this has no effect on the output voltage, as long as at least one conductor segment 5.3 of one resistor track 3 is connected electrically to an adjacent conductor segment 5.4 of the other resistor track 4 via the contacts 9.

The contacts 9 are embodied resiliently and are slightly prestressed toward the conductor segments 5.3, 5.4. For instance, the contacts 9 are embodied as fingerlike spring arms. The contacts 9 are electrically connected to one another via the wiper 8. The contacts 9 are for instance disposed side by side in a row, viewed in the direction of motion R of the wiper 8. In the exemplary embodiment, five contacts 9 are provided. When there are at least four contacts 9, the bridged conductor segments 5.3, 5.4 are each contacted by two contacts 9.

The resistor tracks 3, 4 are connected on at least one end with a respective electrically conductive conductor track 13, 14, whose electrical resistance is much less in comparison to the resistor tracks 3, 4. The conductor tracks 13, 14 are likewise applied two-dimensionally to the substrate 2 by means of thin- or thick-film techniques or in some other way, and made for instance of a metal alloy. On sides oriented toward one another of the conductor tracks 13, 14, some conductor segments 5.3, 5.4 can also be provided, which adjoin the conductor segments 5.3, 5.4 of the resistor tracks 3, 4 and likewise extend into the interstices 10 between the conductor segments 5.4 of the opposed conductor track 14.

For instance, each resistor track 3, 4, on both of its ends, has one conductor track 13, 14, and the conductor tracks 13, 14 facing one another on the left side are connected to electrical terminals 23, 24, and the conductor tracks 13, 14 facing one another on the right side are electrically connected to one another, or in other words are short-circuited, for instance via a resistor 15. An input voltage, for instance in the range between 5 and 16 Volts, is applied to the terminal 23, and an adjustable output voltage, which depends on the position of the wiper 8, is applied to the terminal 24, or vice versa. The output voltage is a component voltage of the input voltage.

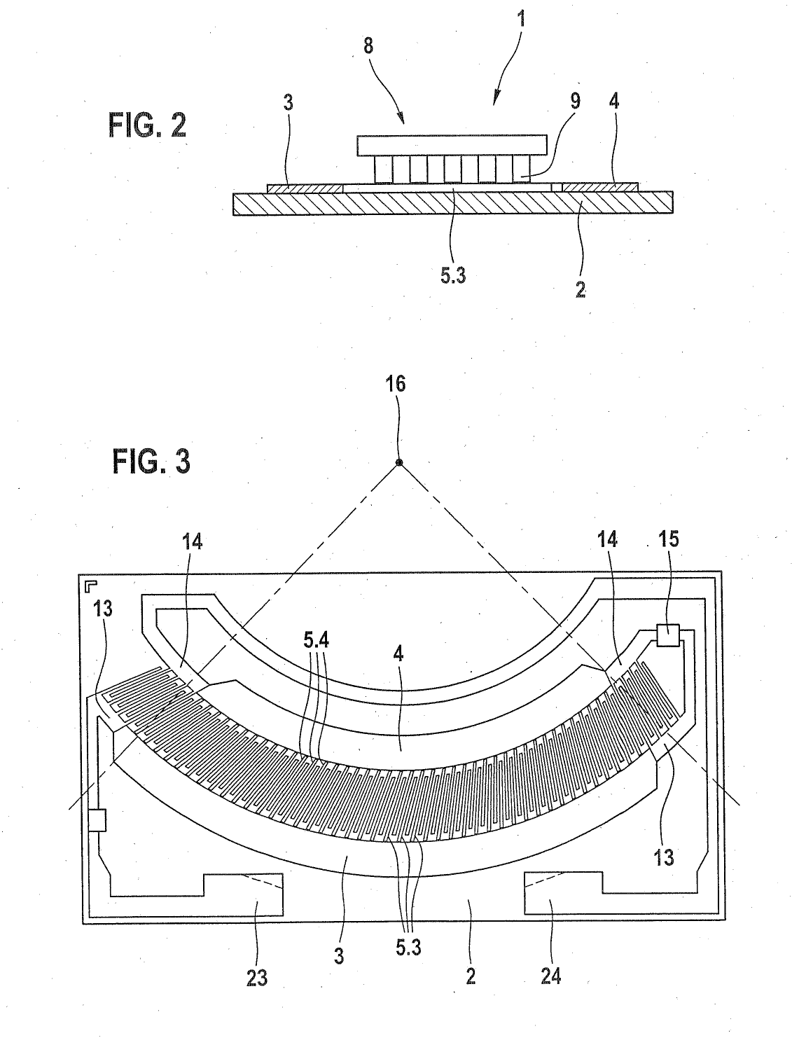

FIG. 2 is a side view of the potentiometer of the invention of FIG. 1.

In the view of FIG. 2, those parts that remain the same or function the same as in the view of FIG. 1 are identified by the same reference numerals.

FIG. 3 is a printed circuit board of a rotary potentiometer according to the invention.

In the rotary potentiometer of FIG. 3, those parts that remain the same or function the same as in the slide potentiometer of FIG. 1 are identified by the same reference numerals.

The conductor segments 5.3, 5.4 of the resistor tracks 3, 4 are inclined in such a way that their imaginary extensions do not extend through a pivot point. 16 of the wiper 8. The conductor segments 5.3, 5.4 and the longitudinal extent of the wiper 8 therefore extend in different directions.

1-8. (canceled)

9. A potentiometer, having two resistor tracks located on an electrically insulating substrate, on each of which resistor track a plurality of spaced-apart conductor segments are provided, which cooperate with a wiper that is movable relative to the substrate, and the conductor segments of one of the two resistor track are offset from the conductor segments of an other of the two resistor track in a direction of motion of the wiper, wherein the conductor segments of the one resistor track extend into interstices between the conductor segments of the other resistor track.

10. The potentiometer of claim 9, wherein the conductor segments of both resistor tracks are each disposed at a predetermined angle to the direction of motion of the wiper.

11. The potentiometer of claim 10, wherein the predetermined angle is in the range between 70 and 80°.

12. The potentiometer of claim 9, wherein there is a respective predetermined spacing between the conductor segment, extending into the interstice, of one resistor track and the two adjacent conductor segments of the other resistor track.

13. The potentiometer of claim 10, wherein there is a respective predetermined spacing between the conductor segment, extending into the interstice, of one resistor track and the two adjacent conductor segments of the other resistor track.

14. The potentiometer of claim 11, wherein there is a respective predetermined spacing between the conductor segment, extending into the interstice, of one resistor track and the two adjacent conductor segments of the other resistor track.

15. The potentiometer of claim 9, wherein the wiper electrically connects a conductor segment of one resistor track to an adjacent conductor segment of the other resistor track.

16. The potentiometer of claim 10, wherein the wiper electrically connects a conductor segment of one resistor track to an adjacent conductor segment of the other resistor track.

17. The potentiometer of claim 11, wherein the wiper electrically connects a conductor segment of one resistor track to an adjacent conductor segment of the other resistor track.

18. The potentiometer of claim 12, wherein the wiper electrically connects a conductor segment of one resistor track to an adjacent conductor segment of the other resistor track.

19. The potentiometer of claim 9, wherein the wiper has at least two spring contacts, connected to one another, which electrically contact the respective conductor segments of the resistor tracks.

20. The potentiometer of claim 12, wherein the wiper has at least two spring contacts, connected to one another, which electrically contact the respective conductor segments of the resistor tracks.

21. The potentiometer of claim 15, wherein the wiper has at least two spring contacts, connected to one another, which electrically contact the respective conductor segments of the resistor tracks.

22. The potentiometer of claim 18, wherein the wiper has at least two spring contacts, connected to one another, which electrically contact the respective conductor segments of the resistor tracks.

23. The potentiometer of claim 9, wherein the wiper has at least four spring contacts, connected to one another, which electrically contact the respective conductor segments of the resistor tracks.

24. The potentiometer of claim 12, wherein the wiper has at least four spring contacts, connected to one another, which electrically contact the respective conductor segments of the resistor tracks.

25. The potentiometer of claim 22, wherein the wiper has at least four spring contacts, connected to one another, which electrically contact the respective conductor segments of the resistor tracks.

26. The potentiometer of claim 9, wherein the wiper has five spring contacts.

27. The potentiometer of claim 12, wherein the wiper has five spring contacts.

28. The potentiometer of claim 25, wherein the wiper has five spring contacts.
